(19) United States
(12) Patent Application Publication
(10) Pub. No.: US 2008/0178924 A1
(43) Pub. Date: Jul. 31, 2008

(54) Photovoltaic cell and method of making thereof

(75) Inventors: Krzysztof Kempa, Billerica, MA (US); Michael Naughton, Norwood, MA (US); Zhifeng Ren, Newton, MA (US)

Correspondence Address: FOLEY AND LARDNER LLP;SUITE 500, 3000 K STREET NW, WASHINGTON, DC, 20007, US

(73) Assignee: Solasta, Inc.

(21) Appl. No.: 12/010,692

(22) Filed: Jan. 29, 2008

Related U.S. Application Data
(60) Provisional application No. 60/887,212, filed on Jan. 30, 2007.
(60) Provisional application No. 60/887,206, filed on Jan. 30, 2007.

(51) Int. Cl. H01L 31/0272; H01L 31/028; H01L 31/0304; H01L 31/0296; H01L 31/042; H01L 31/18

(52) U.S. Cl. 136/244; 136/252; 136/261; 136/264; 136/265; 136/260; 136/263; 438/97; 977/742; 977/762; 977/700; 257/E31.043

(57) ABSTRACT

A photovoltaic cell includes a first electrode, a second electrode, and a photovoltaic material located between and in electrical contact with the first and the second electrodes. The photovoltaic material comprises i) semiconductor nanocrystals having a bang gap that is significantly smaller than peak solar radiation energy to exhibit a multiple exciton effect in response to irradiation by the solar radiation; and/or ii) a first and a second set of semiconductor nanocrystals and the nanocrystals of the first set have a different band gap energy than the nanocrystals of the second set. A width of the photovoltaic material in a direction from the first electrode to the second electrode is less than about 200 nm while a height of the photovoltaic material in a direction substantially perpendicular to the width of the photovoltaic material is at least 1 micron.

### CROSS-REFERENCE TO RELATED PATENT APPLICATIONS

The present application claims benefit of U.S. provisional application 60/887,212, filed Jan. 30, 2007, and U.S. provisional application 60/887,206, filed Jan. 30, 2007, which are both incorporated herein by reference in their entirety.

### BACKGROUND

The present invention relates generally to the field of photovoltaic or solar cells and more specifically to photovoltaic cells containing photovoltaic material which contains multiple band gaps or which exhibits the multiple exciton effect.

An article by Schaller et al. titled “Seven Excitons at a Cost of One: Redefining the Limits for Conversion Efficiency of Photons into Charge Carriers”, Nano Letters, Vol. 6, No. 3 (2006) 424-429, which is incorporated herein by reference in its entirety describes the so-called “multiple exciton” effect in which one photon incident on a photovoltaic (PV) material produces more than one pair of charge carriers, i.e., more than one exciton (i.e., more than one electron-hole pair). The multiple exciton effect is a species of a more general “carrier multiplication” effect for a PV material where the photogenerated charge carriers comprise more than one exciton. It is believed that Schaller's PV material consists of PbSe nanocrystals (also sometimes referred to as single crystal nanoparticles or quantum dots) having an average diameter of less than 30 nm, such as about 20 nm. PbSe has a gap between a conduction band and a valence band (i.e., band gap) of about 0.3 eV, which is several times smaller than the peak emission energy of solar radiation. By irradiating the small band gap nanocrystals with radiation having an energy that is equal to 7.8 PbSe band gap energies (i.e., 0.3 eV×7.8=2.34 eV, the energy of peak solar radiation in the green wavelength range of about 530 nm), the authors were able to generate seven excitons in the nanocrystals for each incident photon, and a quantum efficiency that approaches 700% with an energy conversion efficiency, η, of 65%. The article implies that the multiple exciton effect occurs when the incident radiation has an energy of greater than 2.9 band gap energies of the PV material.

U.S. Published Application 2004/0118451 describes a bulk multijunction PV device with an increased efficiency. The PV device comprises two or more p-n junction cells in semiconductor materials. The multijunction cells may be made of GaInP/GaAs/Ge materials having band gaps of 1.85/1.43/0.7 eV, respectively. Alternatively, each cell may comprise a p-n junction in InGaN material having a different ratio of In to Ga in each cell which provides a different band gap for each cell.

### SUMMARY

An embodiment of the present invention provides a photovoltaic cell includes a first electrode, a second electrode, and a photovoltaic material located between and in electrical contact with the first and the second electrodes. The photovoltaic material comprises i) semiconductor nanocrystals having a bang gap that is significantly smaller than peak solar radiation energy to exhibit a multiple exciton effect in response to irradiation by the solar radiation; and/or ii) a first and a second set of semiconductor nanocrystals, where the nanocrystals of the first set have a different band gap energy than the nanocrystals of the second set. A width of the photovoltaic material in a direction from the first electrode to the second electrode is less than about 200 nm while a height of the photovoltaic material in a direction substantially perpendicular to the width of the photovoltaic material is at least 1 micron.

### BRIEF DESCRIPTION OF THE DRAWINGS

FIG. 1A is a schematic three dimensional view of a PV cell according to an embodiment of the invention. FIGS. 1B and 1D are schematics of band diagrams of the PV cell according to the embodiments of the invention. FIG. 1C is a schematic of radiative transitions between the bands of the PV material of FIG. 1B.

FIG. 2 is a schematic three dimensional view of a PV cell array according to an embodiment of the invention.

FIG. 3A is a schematic top view of a multichamber apparatus for forming the PV cell array according to an embodiment of the invention.

FIGS. 3B-3G are side cross sectional views of steps in a method of forming the PV cell array in the apparatus of FIG. 3A.

FIG. 4A is a side cross sectional schematic view of an integrated multi-level PV cell array. FIG. 4B is a circuit schematic of the array.

FIGS. 5A-5H show side cross sectional views of steps in a method of forming the PV cell array of FIG. 4A.

FIG. 6 is a transmission electron microscope (TEM) image of a carbon nanotube (CNT) conformally-coated with CdTe quantum dot (QD) nanoparticles.

### DETAILED DESCRIPTION OF THE EMBODIMENTS

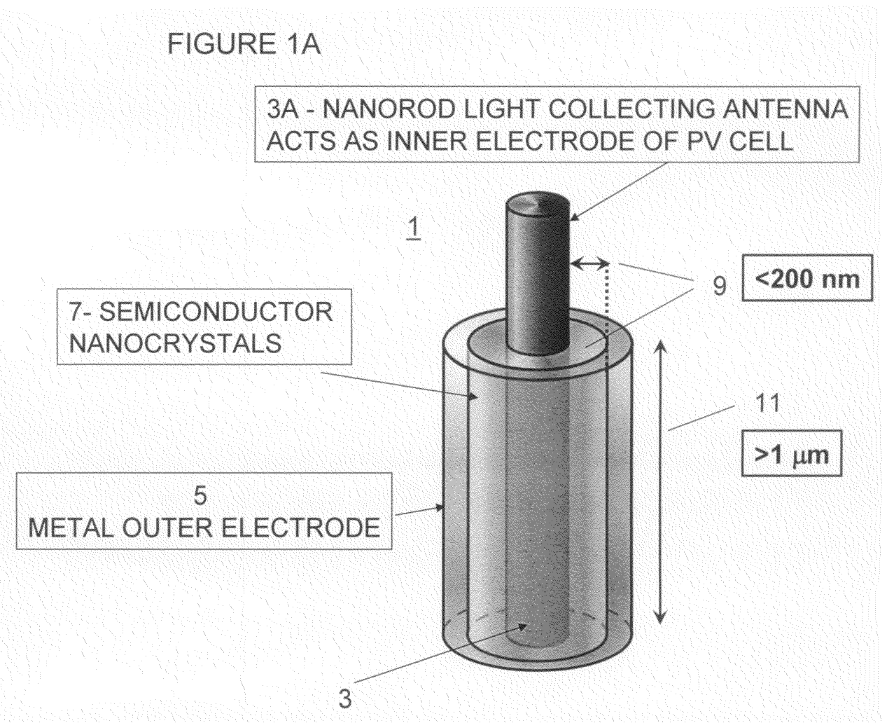

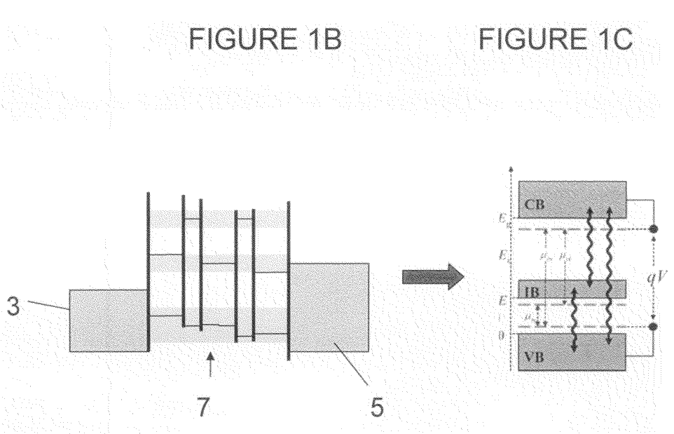

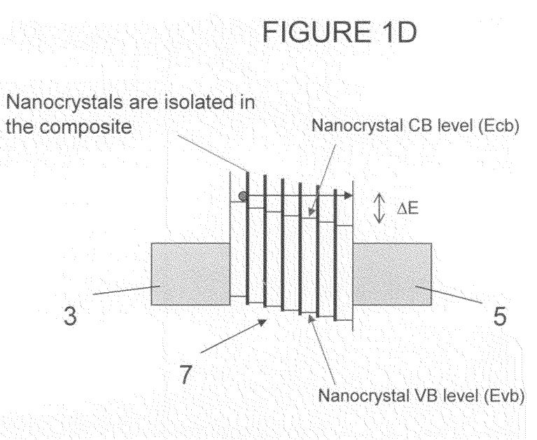

FIG. 1A illustrates a photovoltaic cell 1 according to a first embodiment of the invention. The cell 1 contains a first or inner electrode 3, a second or outer electrode 5, and a photovoltaic (PV) material 7 located between and in electrical contact with the first and the second electrodes. The width 9 of the photovoltaic material in a direction from the first electrode 3 to the second electrode 5 (i.e., left to right in FIG. 1A) is less than about 200 nm, such as 100 nm or less, preferably between 10 and 20 nm. The height 11 of the photovoltaic material (i.e., in the vertical direction in FIG. 1A) in a direction substantially perpendicular to the width of the photovoltaic material is at least 1 micron, such as 2 to 30 microns, for example 10 microns. The term “substantially perpendicular” includes the exactly perpendicular direction for hollow cylinder shaped PV material 7, as well as directions which deviate from perpendicular by 1 to 45 degrees for a hollow conical shaped PV material which has a wider or narrower base than top. Other suitable PV material dimensions may be used.

The width 9 of the PV material 7 preferably extends in a direction substantially perpendicular to incident solar radiation that will be incident on the PV cell 1. In FIG. 1A, the incident solar radiation (i.e., sunlight) is intended to strike the PV material 7 at an angle of about 70 to 110 degrees, such as 85 to 95 degrees, with respect to the horizontal width 9 direction. The width 9 is preferably sufficiently thin to substantially prevent phonon generation during photogenerated charge carrier flight time in the photovoltaic material to the electrode(s). In other words, the PV material 7 width 9 must be thin enough to transport enough charge carriers to the electrode(s) 3 and/or 5 before a significant number of phonons are generated. Thus, when the incident photons of the incident solar radiation are absorbed by the PV material and are converted to charge carriers (electrons/holes or excitons), the charge carriers should reach the respective electrode(s) 3, 5 before a significant amount of phonons are generated (which convert the incident radiation to heat instead of electrical charge carriers which provide a photogenerated electrical current). For example, it is preferred that at least 40%, such as 40-100% of the incident photons are converted to a photogenerated charge carriers which reach a respective electrode and create a photogenerated electrical current instead of generating phonons (i.e., heat). A width 9 of about 10 nm to about 20 nm for the example shown in FIG. 1A is presumed to be small enough to prevent generation of a significant number of phonons. Preferably, the width 9 is sufficiently small to substantially prevent carrier (such as electron and/or hole) energy loss due to carrier recombination and/or scattering. For example, for amorphous silicon, this width is less than about 200 nm. The width may differ for other materials.

The height 11 of the photovoltaic material 7 is preferably sufficiently thick to convert at least 90%, such as 90-100% of incident photons in the incident solar radiation to charge carriers. Thus, the height 11 of the PV material 7 is preferably sufficiently large to collect all the solar radiation. The height 11 is preferably sufficiently large to photovoltaically absorb at least 90%, such as 90-100% of photons in the 50 nm to 2000 nm wavelength range, preferably in the 400 nm to 1000 nm range. Preferably, the height 11 is greater than the longest photon penetration depth in the semiconductor material. Such height is about 1 micron or greater for amorphous silicon. The height may differ for other materials. Preferably, but not necessarily, the height 11 is at least 10 times greater, such as at least 100 times greater, such as 1,000 to 10,000 times greater than the width 9.

The first electrode 3 preferably comprises an electrically conducting nanorod, such as a nanofiber, nanotube or nanowire. For example, the first electrode 3 may comprise an electrically conductive carbon nanotube, such as a metallic multi walled carbon nanotube, or an elemental or alloy metal nanowire, such as molybdenum, copper, nickel, gold, or palladium nanowire, or a nanofiber comprising a nanoscale rope of carbon fibrous material having graphitic sections. The nanorod may have a cylindrical shape with a diameter of 2 to 200 nm, such as 30 to 150 nm, for example 50 nm, and a height of 1 to 100 microns, such as 10 to 30 microns. If desired, the first electrode 3 may also be formed from a conductive polymer material. Alternatively, the nanorod may comprise an electrically insulating material, such as a polymer material, which is covered by an electrically conductive shell to form the electrode 3. For example, an electrically conductive layer may be formed over a substrate such that it forms a conductive shell around the nanorod to form the electrode 3. The polymer nanorods, such as plastic nanorods, may be formed by molding a polymer substrate in a mold to form the nanorods on one surface of the substrate or by stamping one surface of the substrate to form the nanorods.

The photovoltaic material 7 surrounds at least a lower portion of the nanorod electrode 3, as shown in FIG. 1A. The second electrode 5 surrounds the photovoltaic material 7 to form a so-called nanocoax shown in FIG. 1A. The electrode 5 may comprise any suitable conductive material, such as a conductive polymer, or an elemental metal or a metal alloy, such as copper, nickel, aluminum or their alloys. Alternatively, the electrode 5 may comprise an optically transmissive and electrically conductive material, such as a transparent conductive oxide (TCO), such as indium tin oxide, aluminum zinc oxide or indium zinc oxide.

Preferably, but not necessarily, an upper portion of the nanorod 3 extends above the top of photovoltaic material 7 and forms an optical antenna 3A for the photovoltaic cell 1. The term “top” means the side of the PV material 7 distal from the substrate upon which the PV cell is formed. Thus, the nanorod electrode 3 height is preferably greater than the height 11 of the PV material 7. Preferably, the height of the antenna 3A is greater than three times the diameter of the nanorod 3. The height of the antenna 3A may be matched to the incident solar radiation and may comprise an integral multiple of ½ of the peak wavelength of the incident solar radiation (i.e., antenna height=(n/2)×530 nm, where n is an integer). The antenna 3A aids in collection of the solar radiation. Preferably, greater than 90%, such as 90-100% of the incident solar radiation is collected by the antenna 3A.

In an alternative embodiment, the antenna 3A is supplemented by or replaced by a nanohorn light collector. In this embodiment, the outer electrode 5 extends above the PV material 7 height 11 and is shaped roughly as an upside down cone for collecting the solar radiation.

In another alternative embodiment, the PV cell 1 has a shape other than a nanocoax. For example, the PV material 7 and/or the outer electrode 5 may extend only a part of the way around the inner electrode 3. Furthermore, the electrodes 3 and 5 may comprise plate shaped electrodes and the PV material 7 may comprise thin and tall plate shaped material between the electrodes 3 and 5.

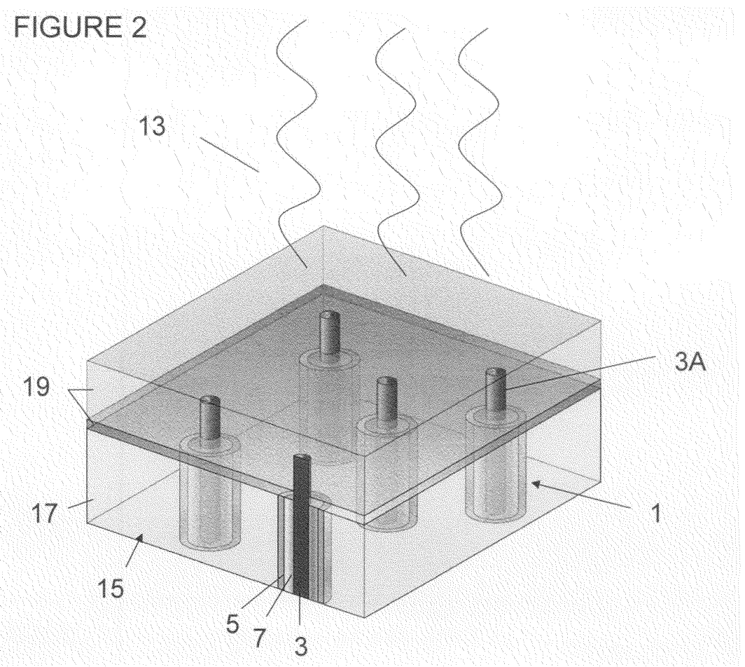

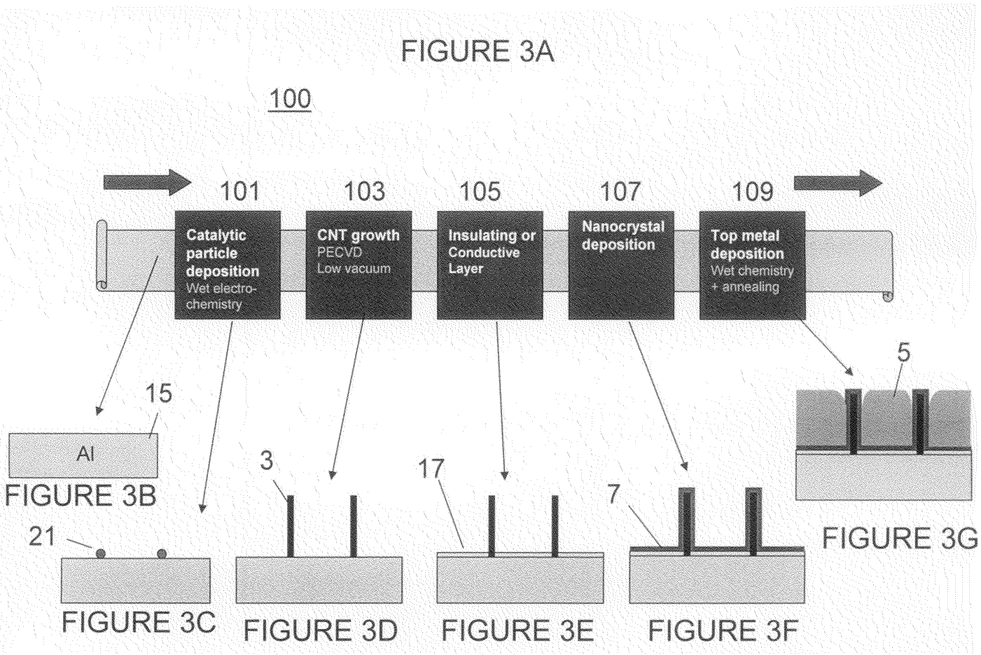

FIG. 2 illustrates an array of nanocoax PV cells 1 in which the antenna 3A in each cell 1 collects incident solar radiation, which is schematically shown as lines 13. As shown in FIGS. 2, 3B, 3D and 3G, the nanorod inner electrodes 3 may be formed directly on a conductive substrate 15, such as a steel or aluminum substrate. In this case, the substrate acts as one of the electrical contacts which connects the electrodes 3 and PV cells 1 in series. For a conductive substrate 15, an optional electrically insulating layer 17, such as silicon oxide or aluminum oxide, may be located between the substrate 15 and each outer electrode 5 to electrically isolate the electrodes 5 from the substrate 15, as shown in FIG. 3E. The insulating layer 17 may also fill the spaces between adjacent electrodes 5 of adjacent PV cells 1, as shown in FIG. 2. Alternatively, if the PV material 7 covers the surface of the substrate 15 as shown in FIG. 3F, then the insulating layer 17 may be omitted. In another alternative configuration, as shown in FIG. 3G, the entire lateral space between the PV cells may be filled with the electrode 5 material if it is desired to connect all electrodes 5 in series. In this configuration, the electrode 5 material may be located above the PV material 7 which is located over the substrate in a space between the PV cells. If desired, the insulating layer 17 may be either omitted entirely or it may comprise a thin layer located below the PV material as shown in FIG. 3G. One electrical contact (not shown for clarity) is made to the outer electrodes 5 while a separate electrical contact is connected to inner electrodes through the substrate 15. Alternatively, an insulating substrate 15 may be used instead of a conductive substrate, and a separate electrical contact is provided to each inner electrode 3 below the PV cells. In this configuration, the insulating layer 17 shown in FIG. 3G may be replaced by an electrically conductive layer. The electrically conductive layer 17 may contact the base of the inner electrodes 3 or it may cover each entire inner electrode 3 (especially if the inner nanorods are made of insulating material). If the substrate 15 comprises an optically transparent material, such as glass, quartz or plastic, then nanowire or nanotube antennas may be formed on the opposite side of the substrate from the PV cell. In the transparent substrate configuration, the PV cell may be irradiated with solar radiation through the substrate 15. An electrically conductive and optically transparent layer 17, such as an indium tin oxide, aluminum zinc oxide, indium zinc oxide or another transparent, conductive metal oxide may be formed on the surface of a transparent insulating substrate to function as a bottom contact to the inner electrodes 3. Such conductive, transparent layer 17 may contact the base of the inner electrodes 3 or it may cover the entire inner electrodes 3. Thus, the substrate 15 may be flexible or rigid, conductive or insulating, transparent or opaque to visible light.

Preferably, one or more insulating, optically transparent encapsulating and/or antireflective layers 19 are formed over the cells 1. The antennas 3A may be encapsulated in one or more encapsulating layer(s) 19. The encapsulating layer(s) 19 may comprise a transparent polymer layer, such as EVA or other polymers generally used as encapsulating layers in PV devices, and/or an inorganic layer, such as silicon oxide or other glass layers.

In one aspect of the present invention, the photovoltaic material 7 comprises a material having two or more different band gaps. The band gaps may range from 0.1 eV to 4 eV, for example from 0.3 eV to 3.4 eV, such as 0.3 eV to 1.85 eV. The photovoltaic material may comprise either bulk and/or nanocrystal material. The band gap diagram of the PV cell is illustrated in FIG. 1B and the radiative transitions between the conduction, valence and intermediate bands of the PV material 7 are illustrated in FIG. 1C.

In one embodiment of the invention, the photovoltaic material 7 comprises two or more sets of nanocrystals (also known as nanoparticles or quantum dots) with different band gap energies. As used herein, a “set” of nanocrystals means a group of nanocrystals having about the same band gap. Preferably, the nanocrystals have an average diameter of 1 to 100 nm, such as 1 to 10 nm, for example 1 to 5 nm. The nanocrystals are in physical or tunneling contact with each other to provide a path for charge carriers from the inner electrode 3 to the outer electrode 5. The nanocrystals may be encapsulated in an optically transparent matrix material, such as an optically transparent polymer matrix (for example EVA or other polymer encapsulating materials used in solar cells) or optically transparent inorganic oxide matrix material, such as glass, silicon oxide, etc. Small distance between the nanocrystals in the matrix assures carrier tunneling in absence of direct carrier transport between adjacent nanoparticles. Alternatively, the matrix may be omitted and the nanocrystals may comprise a densely packed nanocrystal body. The nanocrystal PV material 7 is preferably used in the vertical nanocoax type PV cell 1 configuration shown in FIGS. 1 and 2. However, any other PV cell configuration may be used, including a planar horizontal configuration in which the nanocrystal PV material is located between two planar electrodes, one of which is transparent to radiation (i.e., the solar radiation is incident on a major surface of a horizontal transparent electrode and the radiation is transmitted to the PV material through the transparent electrode).

The different band gap energies may be obtained by varying the material of the nanocrystals and/or by varying the size of the same material nanocrystals. For example, nanocrystals of the same size but made of different nanocrystal materials, such as Si, SiGe and PbSe, for example, have a different band gap energies due to the intrinsic material band gap structure. Furthermore, for nanocrystals having a diameter less than a certain critical diameter, the band gap increases with decreasing diameter due to quantum effects of the strong confinement regime. The critical diameter below which the band gap of the semiconductor nanocrystal varies with size is different for different materials, but is generally believed to be below one exciton Bohr radius for a particular material. For example, it is believed that the size of the exciton Bohr radius is about 5-6 nm for CdSe and over 40 nm for PbSe.

Thus, in the present embodiment, the photovoltaic material may comprise nanocrystals of two or more different materials and/or nanocrystals of the same or different material having a different average diameter, where the diameter of at least one set of nanocrystals is smaller than the exciton Bohr radius for the nanocrystal material. The nanocrystals may comprise unitary, binary, ternary or quaternary nanocrystals of Group IV, IV-IV, III-V, II-VI, IV-VI and I-III-VI materials or organic, polymeric or other semiconductor materials. For example, the photovoltaic material may comprise Si, SiGe and PbSe nanocrystals having different band gaps. Alternatively, the photovoltaic material may comprise PbSe nanocrystals of two or more diameters below 40 nm, such as two to four sets of nanocrystals having different average diameters and thus different band gap energies in each set. Of course the sets of nanocrystals may be selected such that they have different band gap energies due to both composition and diameter. In general, the PV material 7 may comprise between two and ten nanocrystals sets to provide between two and ten different band gaps. As shown in FIG. 1C, for PV material having N bands (where N≧3), there are N(N−1)/2 band gaps which leads to N(N−1)/2 absorptions and radiative transitions between bands.

Each set of nanocrystals may be provided separately in the PV material 7 or it may be intermixed with the other set(s) of nanocrystals. For example, with reference to FIG. 1A, the nanocrystal sets may be separated in the height 11 direction. In this configuration, one set of nanocrystals having the smallest band gap may be positioned on the bottom of the PV material (i.e., closest to the substrate 15) while another set of nanocrystals having the largest band gap may be positioned closest to the top of the PV material (i.e., closest to the antenna 3A). If additional one or more sets of nanocrystals having an intermediate band gap are present, then they can be provided in the middle of the PV material between the other two sets.

In another configuration, the nanocrystals may be separated in the width 9 direction. In one such configuration, one set of nanocrystals having the smallest band gap may be positioned closest to the outer electrode 5 while another set of nanocrystals having the largest band gap may be positioned closest to the inner electrode 3. If additional sets of nanocrystals having an intermediate band gap are present, then they can be provided in the middle of the PV material between the other two sets. In an alternative configuration, the first set of nanocrystals having the smallest band gap may be positioned closest to the inner electrode 3 while the second set of nanocrystals having the largest band gap may be positioned closest to the outer electrode 5.

In another configuration, the nanocrystal sets are not separated but are mixed together. Thus, the nanocrystals of all sets are mixed together in the matrix material or in a packed nanocrystal body PV material 7.

In another embodiment of the present invention, the nanocrystals have a band gap that is significantly smaller than peak solar radiation energy to exhibit the multiple exciton effect (also known as the carrier multiplication effect) in response to irradiation by solar radiation. Preferably, the nanocrystals have a band gap which is equal to or less than 0.8 eV, such as 0.1 to 0.8 eV (i.e., at least 2.9 times smaller than the 2.34 eV peak energy of solar radiation). These nanocrystals may be sufficiently large (i.e., having a diameter larger than the Exciton Bohr Radius) such that their band gap is determined by their material composition rather than their size (i.e., the band gap is the property of the material rather than size). Thus, the selection of the small band gap material to exhibit the multiple exciton effect as well as the large height to width ratio of the PV material 7 provide improved color matching for the PV cell 1 (i.e., an improved ability of the PV material to generate charge carriers from incident photons without significant generation of phonons/heat). FIG. 1D illustrates a band diagram of the PV cell 1 of this embodiment. In this embodiment, the photovoltaic material 7 may comprise semiconductor nanocrystals having either the same band gap energies or different band gap energies (i.e., the photovoltaic material may comprise either one set, or two or more sets of nanocrystals). Thus, the PV material 7 may comprise a first set of nanocrystals having a band gap of 0.8 eV or smaller, and optionally one or more second sets of nanocrystals having a band gap of 0.9 to 3.4 eV, such as 1 to 2.34 eV, for example, 1.43 to 1.85 eV.

Any suitable semiconductor nanocrystals, such as small direct band gap semiconductor nanocrystals, which generate multiple excitons per photon in response to solar radiation may be used. Examples of nanocrystal materials include inorganic semiconductors, such as Ge, SiGe, PbSe, PbTe, SnTe, SnSe, Bi₂Te₃, Sb₂Te₃, PbS, Bi₂Se₃, InAs, InSb, CdTe, CdS or CdSe as well as ternary and quaternary combinations thereof.

Alternatively, the PV material may include other PV active materials which exhibit the carrier multiplication effect, such as bulk inorganic semiconductor layers having band gaps of 0.8 eV or less (as described above), photoactive polymers (such as semiconducting polymers), organic photoactive molecular materials, such as dyes, or a biological photoactive materials, such as biological semiconductor materials. Photoactive means the ability to generate charge carriers (i.e., a current) in response to irradiation by solar radiation. Organic and polymeric materials include polyphenylene vinylene, copper phthalocyanine (a blue or green organic pigment) or carbon fullerenes. Biological materials include proteins, rhodonines, or DNA (e.g. deoxyguanosine, disclosed in Appl. Phys. Lett. 78, 3541 (2001) incorporated herein by reference).

The PV material 7 may consist entirely of the nanocrystals described above. This forms a Schottky junction type PV cell 1. In an alternative configuration, a p-n or p-i-n type PV cell 1 is formed. In the p-n or p-i-n type PV cell, the PV material contains a p-n or p-i-n junction. For example, the PV material 7 may comprise intrinsic nanocrystals which are located between semiconductor thin films of opposite conductivity type to form the p-i-n type PV cell. In the p-i-n PV cell, a first p or n type semiconductor thin film is formed around the inner electrode 3. Then, the nanocrystal containing intrinsic region is formed around the first semiconductor thin film. Then, a second n or p type semiconductor thin film of the opposite conductivity type to the first semiconductor thin film is formed around the nanocrystal intrinsic region. Each semiconductor thin film may have a thickness of about 2 to 500 nm, such as 5 to about 30 nm such as about 5 to about 20 nm. For example, the PV material may comprise a three-layer film containing: i) a bulk semiconductor layer (such as heavily doped, p-type amorphous or polycrystalline silicon or other semiconductor layer), ii) a semiconductor nanocrystal layer (such as intrinsic silicon or other nanocrystal film); and iii) a bulk semiconductor layer (such as heavily doped, n-type amorphous or polycrystalline silicon or other semiconductor layer) to form a p-i-n type PV cell with the nanocrystal intrinsic layer located between the bulk p and n-type layers. These layers are arranged in order from the inner electrode 3 to the outer electrode 5. The nanocrystal layer may comprise silicon nanocrystals made by the layer-by-layer method or other methods (see for example, N. Malikova, et al., Langmuir 18 (9) (2002) 3694, incorporated herein by reference, for a general description of the layer-by-layer method). This configuration provides a maximum internal electric field of about 1V (Si gap), and will reduce or eliminate short circuits. The bulk silicon layers may be about 5-10 nm thick and the nanocrystal layer may be about 10-30 nm thick. In general, the intrinsic layer may be 10 to 200 nm thick and the p and n-type layers may be 2 to 50 nm thick. Each of the p, i and n type layers may comprise a silicon or a non-silicon semiconductor material, in any suitable combination. For example, the intrinsic layer may comprise a different semiconductor material from the p and n-type layers. It should be noted that the bulk/nanocrystal/bulk p-i-n PV cell may have configurations other than the coax configurations and may be positioned horizontally instead of vertically.

FIG. 3A illustrates a multichamber apparatus 100 for making the PV cells and FIGS. 3B-3G illustrate the steps in a method of making the PV cells 1 according to one embodiment of the invention. As shown in FIGS. 3A and 3B, the PV cells 1 may be formed on a moving conductive substrate 15, such as on an continuous aluminum or steel web or strip which is spooled (i.e., unrolled) from one spool or reel and is taken up onto a take up spool or reel. The substrate 15 passes through several deposition stations or chambers in a multichamber deposition apparatus. Alternatively, a stationary, discreet substrate (i.e., a rectangular substrate that is not a continuous web or strip) may be used.

First, as shown in FIG. 3C, nanorod catalyst particles 21, such as iron, cobalt, gold or other metal nanoparticles are deposited on the substrate in chamber or station 101. The catalyst particles may be deposited by wet electrochemistry or by any other known metal catalyst particle deposition method. The catalyst metal and particle size are selected based on the type of nanorod electrode 3 (i.e., carbon nanotube, nanowire, etc.) that will be formed.

In a second step shown in FIG. 3D, the nanorod electrodes 3 are selectively grown in chamber or station 103 at the nanocrystal catalyst sites by tip or base growth, depending on the catalyst particle and nanorod type. For example, carbon nanotube nanorods may be grown by PECVD in a low vacuum, while metal nanowires may be grown by MOCVD. The nanorod electrodes 3 are formed perpendicular to the substrate 15 surface. Alternatively, the nanorods may be formed by molding or stamping, as described above.

In a third step shown in FIG. 3E, an optional the insulating layer 17 is formed on the exposed surface of substrate 15 around the nanorod electrodes 3 in chamber or station 105. The insulating layer 17 may be formed by low temperature thermal oxidation of the exposed metal substrate surface in an air or oxygen ambient, or by deposition of an insulating layer, such as silicon oxide, by CVD, sputtering, spin-on glass deposition, etc. Alternatively, the optional layer 17 may comprise an electrically conductive layer, such as a metal or a conductive metal oxide layer formed by sputtering, plating, etc.

In a fourth step shown in FIG. 3F, the nanocrystal PV material 7 is formed over and around the nanorod electrodes 3 and over the optional insulating layer 17 in chamber or station 107. Several different methods may be used to deposit the PV material 7.

One method of forming the PV material comprises depositing continuous semiconductor film or films having a width 9 less than 20 nm using any suitable vapor deposition technique around nanorod shaped inner electrodes 3. Due to the nanoscale surface curvature of the nanorods 3, the film will contain nanocrystals or quantum dots. To form at least two sets of nanocrystals with different band gap energies, at least two films with different compositions from each other are deposited in sequence.

Another method of forming the PV material comprises providing prefabricated semiconductor nanocrystals by separately forming or obtaining commercial semiconductor nanocrystals. The semiconductor nanocrystals are then attached to at least a lower portion of a nanorod shaped inner electrodes 3 to form the photovoltaic material comprised of nanocrystals. For example, the nanocrystals may be provided from a nanocrystal solution or suspension over the insulating layer 17 and over the electrodes 3. If desired, the nanorod electrodes 3, such as carbon nanotubes, may be chemically functionalized with moieties, such as reactive groups which bind to the nanocrystals using van der Waals attraction or covalent bonding. To form at least two sets of nanocrystals with different band gap energies, the different nanocrystals can be premixed before deposition.

Another method of forming the PV material comprises providing prefabricated nanocrystals and placing the semiconductor nanocrystals in an optically transparent polymer matrix, such as an EVA or other matrix. The polymer matrix containing the semiconductor nanocrystals is then deposited over the substrate 15 and around the nanorod shaped inner electrodes 3 to form a composite photovoltaic material comprised of nanocrystals in the polymer matrix. To form at least two sets of nanocrystals with different band gap energies, the nanocrystals can be mixed into the same polymer matrix. Alternatively, each set of nanocrystals may be provided into a separate matrix and then the matrixes can be separately deposited into the PV cell.

Another method of forming the PV material comprises depositing a first transparent oxide layer, such as a glass layer, over the substrate 15 and around a lower portion of nanorod shaped inner electrodes 3. The glass layer may be deposited by sputtering, CVD or spin-on coating. This is followed by depositing the semiconductor nanocrystals over the transparent oxide. The nanocrystals may be formed in-situ by CVD on the transparent oxide, or prefabricated nanocrystals may be deposited on the oxide from a solution or suspension. Then, a second transparent oxide layer is deposited over the deposited semiconductor nanocrystals to form a composite PV material comprised of nanocrystals in a transparent oxide matrix. The above deposition steps may be repeated several times until a desired thickness is achieved. To form at least two sets of nanocrystals with different band gap energies, both sets of nanocrystals may be mixed with each other into each nanocrystal layer or each set of nanocrystals may be provided into a separate nanocrystal layer separated by the oxide layer.

In a fifth step shown in FIG. 3G, the outer electrode 5 is formed around the photovoltaic material 7 in chamber or station 109. The outer electrode 5 may be formed by a wet chemistry method, such as by Ni or Cu electroless plating or electroplating following by an annealing step. Alternatively, the electrode 5 may be formed by PVD, such as sputtering or evaporation. The outer electrode 5 and the PV material 7 may be polished by chemical mechanical polishing and/or selectively etched back to planarize the upper surface of the PV cells 1 and to expose the upper portions of the nanorods 3 to form the antennas 3A. If desired, an additional insulating layer may be formed between the PV cells. The encapsulation layer 19 is then formed over the antennas 3A to complete the PV cell array.

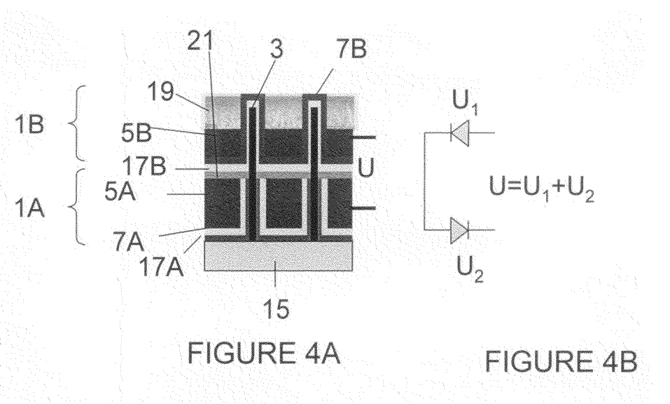

FIG. 4A illustrates a multi-level array of PV cells formed over the substrate 15. In this array, the each PV cell 1A in the lower level shares the inner nanorod shaped electrode 3 with an overlying PV cell 1B in the upper level. In other words, the electrode 3 extends vertically (i.e., perpendicular with respect to the substrate surface) through at least two PV cells 1A, 1B. However, the cells in the lower and upper levels of the array contain separate PV material 7A, 7B, separate outer electrodes 5A, 5B, and separate electrical outputs U1 and U2. Different type of PV material (i.e., different nanocrystal size, band gap and/or composition) may be provided in the cells 1A of the lower array level than in the cells 1A of the upper array level. An insulating layer 21 is located between the upper and lower PV cell levels. The inner electrodes 3 extend through this layer 21. While two levels are shown, three or more device levels may be formed. Furthermore, the inner electrode 3 may extend above the upper PV cell 1B to form an antenna. FIG. 4B illustrates the circuit schematic of the array of FIG. 4A.

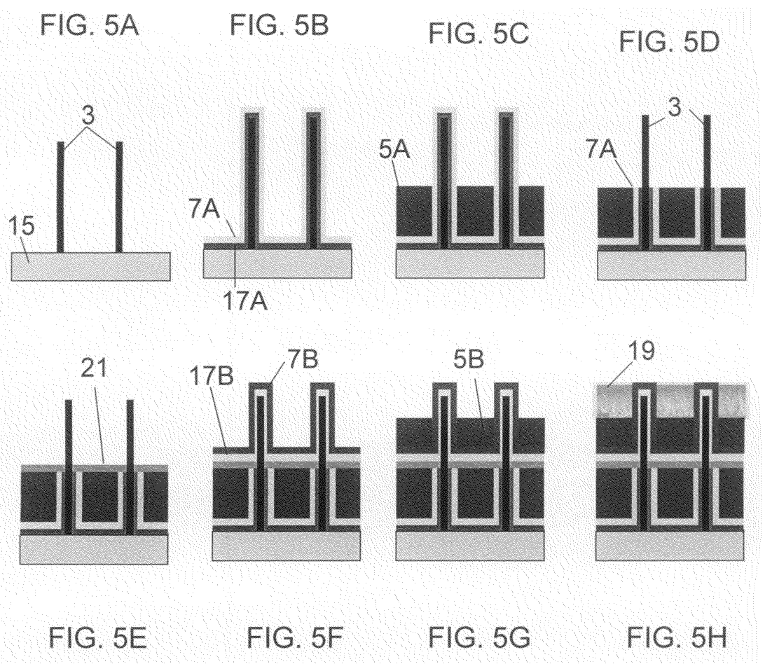

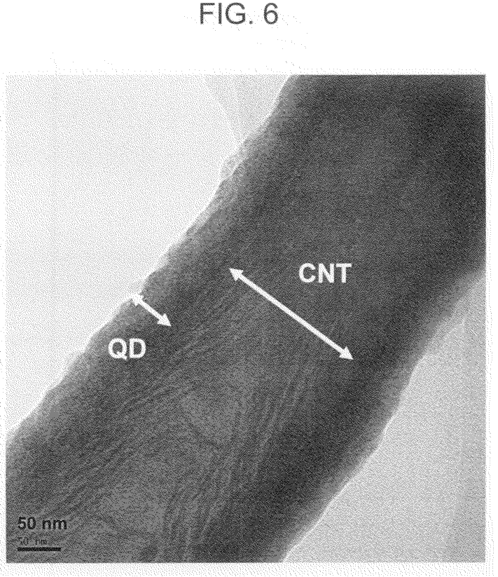

FIG. 5A-5H illustrate the steps in the method of making the array of FIG. 4A. The method is similar to the method of FIGS. 3B to 3G and may be performed in the apparatus of FIG. 3A. Specifically, the steps shown in FIGS. 3B to 3G are repeated in FIGS. 5A-5D to form the PV cells 1A in the lower level of the array, except that a large portion of the inner electrode is exposed above the PV material and the outer electrode. As shown in FIGS. 5E-5H, the steps shown in FIGS. 3E to 3G are repeated again to form the upper level of PV cells 1B of the array. Additional device levels may be formed by repeating the steps of FIGS. 3E to 3G one or more additional times. Specifically, as shown in FIG. 5A, the nanorod inner electrodes 3 are formed on the substrate 15. Then, the optional conductive or insulating layer 17A and photovoltaic layer 7A are formed over and between the electrodes 3, as shown in FIG. 5B. For example, layer 17A shown in FIG. 5B may be a conductive layer which acts as a contact. Then, the outer electrodes 5A are formed in the space between the PV layer 7A covered inner electrodes 3, as shown in FIG. 5C. The outer electrodes 5A may be formed by forming a conductive layer (such as a metal or a conductive metal oxide layer) over the inner electrodes 3 followed by a selective etch of the conductive layer to reduce its thickness to expose the PV layer 7A on the sides of electrodes 3. Alternatively, the outer electrodes 5A may be deposited to a thickness that is less than the height of the electrodes 3 to avoid the etch. The first photovoltaic layer 7A and the optional layer 17A are selectively etched to recess them to the same height as the electrodes 5A and to expose the sides of the inner electrodes 3, as shown in FIG. 5D. Then, as shown in FIG. 5E, an interlayer insulating layer 21 is formed over the first device level 1A. Layer 21 may be a silicon oxide, silicon nitride, spin-on dielectric, etc., layer through which the inner electrodes 3 are exposed. Then, the optional conductive or insulating layer 17B and second photovoltaic layer 7B is formed over and between the electrodes 3, as shown in FIG. 5F. For example, layer 17B shown in FIG. 5F may be a conductive layer which acts as a contact. Then, the outer electrodes 5B are formed in the space between the PV layer 7B covered inner electrodes 3, as shown in FIG. 5G. Insulating passivation and/or antireflective layer(s) 19 are then formed over the outer electrodes 5B to fill the space between the inner electrodes, as shown in FIG. 5H. The PV layer 7A, 7B materials may be chosen such that the material which will be exposed to solar radiation first has a larger band gap (which absorbs shorter wavelength/larger energy radiation) than that of the material which will be exposed to solar radiation second. Thus, the material that is exposed to solar radiation first (through the substrate 15 or from the opposite side to the substrate 15 depending on the device design) absorbs shorter wavelength radiation and allows longer wavelength radiation to pass through to the other material, where such longer wavelength radiation is absorbed. FIG. 6 is an exemplary TEM image of a carbon nanotube (CNT) conformally-coated with CdTe nanocrystals (quantum dot (QD) nanoparticles).

A method of operating the PV cell 1 includes exposing the cell 1 to incident solar radiation 13 propagating in a first direction, as shown in FIG. 2, and generating a current from the PV cell in response to the step of exposing, such that the PV material 7 contains at least two sets of nanocrystals having different band gaps and/or exhibits a carrier multiplication effect, such as the multiple exciton effect, which is a subset of the carrier multiplication effect. As discussed above, the width 9 of the PV material 7 between the inner 3 and the outer 5 electrodes in a direction substantially perpendicular to the radiation 13 direction is sufficiently thin to substantially prevent phonon generation during photogenerated charge carrier flight time in the photovoltaic material to at least one of the electrodes and/or to substantially prevent charge carrier energy loss due to charge carrier recombination and scattering. The height 11 of the PV material 7 in a direction substantially parallel to the radiation 13 direction is sufficiently thick to convert at least 90%, such as 90-100% of incident photons in the incident solar radiation to charge carriers, such as excitons and/or to photovoltaically absorb at least 90%, such as 90-100% of photons in a 50 to 2000 nm, preferably a 400 nm to 1000 nm wavelength range.

The foregoing description of the invention has been presented for purposes of illustration and description. It is not intended to be exhaustive or to limit the invention to the precise form disclosed, and modifications and variations are possible in light of the above teachings or may be acquired from practice of the invention. The description was chosen in order to explain the principles of the invention and its practical application. It is intended that the scope of the invention be defined by the claims appended hereto, and their equivalents.

1. A photovoltaic cell, comprising:
a first electrode;
a second electrode; and
a photovoltaic material comprising semiconductor nanocrystals located between and in electrical contact with the first and the second electrodes;
wherein:
the semiconductor nanocrystals comprise at least one of:
a) semiconductor nanocrystals having a band gap that is significantly smaller than peak solar radiation energy, such that the photovoltaic material exhibits a multiple exciton effect in response to irradiation by the solar radiation; or
b) semiconductor nanocrystals comprise a first and a second set of the semiconductor nanocrystals, wherein the nanocrystals of the first set have a different band gap energy than the nanocrystals of the second set;
a width of the photovoltaic material in a direction from the first electrode to the second electrode is less than about 200 nm; and
a height of the photovoltaic material in a direction substantially perpendicular to the width of the photovoltaic material is at least 1 micron.

2. The cell of claim 1, wherein:
the width of the photovoltaic material in a direction substantially perpendicular to an intended direction of incident solar radiation is sufficiently thin to substantially prevent charge carrier energy loss due to charge carrier recombination and scattering; and
the height of the photovoltaic material in a direction substantially parallel to the intended direction of incident solar radiation is sufficiently thick to photovoltaically absorb at least 90% of photons in a 50 to 2000 nm wavelength range.

3. The cell of claim 1, wherein:
the width of the photovoltaic material in a direction substantially perpendicular to an intended direction of incident solar radiation is sufficiently thin to substantially prevent phonon generation during photogenerated charge carrier flight time in the photovoltaic material to at least one of the first and to the second electrodes; and
the height of the photovoltaic material in a direction substantially parallel to the intended direction of incident solar radiation is sufficiently thick to convert at least 90% of incident photons in the incident solar radiation to charge carriers.

4. The cell of claim 1, wherein:
the width of the photovoltaic material is between 10 and 20 nm; and
the height of the photovoltaic material is at least 2 to 30 microns.

5. The cell of claim 1, wherein:
the first electrode comprises a nanorod;
the photovoltaic material surrounds at least a lower portion of the nanorod; and
the second electrode surrounds the photovoltaic material to form a nanocoax.

6. The cell of claim 5, wherein the nanorod comprises a carbon nanotube or an electrically conductive nanowire.

7. The cell of claim 5, wherein an upper portion of the nanorod extends above the photovoltaic material and forms an optical antenna for the photovoltaic cell.

8. The cell of claim 1, wherein:
the nanocrystals comprise the first and the second set of the semiconductor nanocrystals; and
the nanocrystals of the first set comprise at least one of different composition or different average diameter from the nanocrystals of the second set.

9. The cell of claim 8, wherein the photovoltaic material further comprises a third set of nanocrystals, wherein the nanocrystals of the third set have a different band gap energy than the nanocrystals of the first and the second sets.

10. The cell of claim 8, wherein the nanocrystals of at least the first set have a band gap that is significantly smaller than peak solar radiation energy, such that the photovoltaic material exhibits a multiple exciton effect in response to irradiation by the solar radiation.

11. The cell of claim 1, wherein the nanocrystals have a band gap that is significantly smaller than peak solar radiation energy, such that the photovoltaic material exhibits a multiple exciton effect in response to irradiation by the solar radiation.

12. The cell of claim 11, wherein the nanocrystals have a band gap between 0.1 eV to 0.8 eV.

13. The cell of claim 12, wherein the nanocrystals are selected from a group consisting of Ge, SiGe, PbSe, PbTe, SnTe, SnSe, Bi₂Te₃, Sb₂Te₃, PbS, Bi₂Se₃, InAs, InSb, CdTe, CdS or CdSe.

14. The cell of claim 1, wherein the PV cell comprises a portion of an array of PV cells.

15. The cell of claim 1, wherein the nanocrystals are located in an optically transparent matrix material comprising an optically transparent polymer or optically transparent inorganic oxide matrix material.

16. The cell of claim 1, wherein the photovoltaic material further comprises a first semiconductor thin film of a first conductivity type and a second semiconductor thin film of a second conductivity type opposite to the first conductivity type, positioned such that the semiconductor nanocrystals are located between the first and the second semiconductor thin films.

17. A photovoltaic cell, comprising:
a first electrode;
a second electrode; and
a photovoltaic material comprising semiconductor nanocrystals located between and in electrical contact with the first and the second electrodes;
wherein:
the photovoltaic material comprises a first and a second set of semiconductor nanocrystals; and
the nanocrystals of the first set have a different band gap energy than the nanocrystals of the second set.

18. A photovoltaic cell, comprising:
a first electrode;
a second electrode; and
a photovoltaic material located between and in electrical contact with the first and the second electrodes;
wherein:
the photovoltaic material comprises a bulk inorganic semiconductor material, a polymer photoactive material, an organic molecular photoactive material or a biological photoactive material;
the photovoltaic material exhibits a carrier multiplication effect in response to irradiation by solar radiation;
a width of the photovoltaic material in a direction from the first electrode to the second electrode is less than 200 nm; and
a height of the photovoltaic material in a direction substantially perpendicular to the width of the photovoltaic material is at least 1 micron.

19. A method of making a photovoltaic cell, comprising:
forming a first electrode;
forming a second electrode; and
forming a photovoltaic material comprising semiconductor nanocrystals located between and in electrical contact with the first and the second electrodes;
wherein:
the semiconductor nanocrystals comprise at least one of:
a) semiconductor nanocrystals having a band gap that is significantly smaller than peak solar radiation energy, such that the photovoltaic material exhibits a multiple exciton effect in response to irradiation by the solar radiation; or
b) semiconductor nanocrystals comprise a first and a second set of the semiconductor nanocrystals, wherein the nanocrystals of the first set have a different band gap energy than the nanocrystals of the second set;
a width of the photovoltaic material in a direction from the first electrode to the second electrode is less than about 200 nm; and
a height of the photovoltaic material in a direction substantially perpendicular to the width of the photovoltaic material is at least 1 micron.

20. The method of claim 19, further comprising:
forming the first electrode perpendicular to a substrate;
forming the photovoltaic material around the first electrode; and
forming the second electrode around the photovoltaic material.

21. The method of claim 20, wherein the step of forming the photovoltaic material comprises depositing at least one continuous semiconductor film having a width less than 20 nm using a vapor deposition technique around a nanorod shaped first electrode to form the photovoltaic material comprised of nanocrystals.

22. The method of claim 20, wherein the step of forming the photovoltaic material comprises providing the semiconductor nanocrystals followed by attaching the provided semiconductor nanocrystals to at least a lower portion of a nanorod shaped first electrode.

23. The method of claim 20, wherein the step of forming the photovoltaic material comprises:
providing the semiconductor nanocrystals;
placing the provided semiconductor nanocrystals in an optically transparent polymer matrix; and
depositing the polymer matrix containing the semiconductor nanocrystals around a nanorod shaped first electrode.

24. The method of claim 20, wherein the step of forming the photovoltaic material comprises:
(a) depositing a first transparent oxide layer around a lower portion of a nanorod shaped first electrode;
(b) depositing the semiconductor nanocrystals over the transparent oxide; and
(c) depositing a second transparent oxide layer over the deposited semiconductor nanocrystals.

25. The method of claim 19, wherein the first and the second electrodes and the photovoltaic material are deposited on a moving conductive substrate.

26. The method of claim 25, further comprising forming an array of photovoltaic cells on the substrate.

27. The method of claim 26, further comprising:
spooling a web shaped electrically conductive substrate from a first reel to a second reel;
forming a plurality of metal catalyst particles on the conductive substrate;
growing a plurality of nanorod shaped first electrodes from the metal catalyst particles;
forming the photovoltaic material around the first electrodes; and
forming a plurality of the second electrodes around the photovoltaic material.

28. The method of claim 19, wherein:
the nanocrystals comprise the first and the second set of the semiconductor nanocrystals; and
the nanocrystals of the first set comprise at least one of different composition or different average diameter from the nanocrystals of the second set.

29. The method of claim 19, wherein the nanocrystals of have a band gap that is significantly smaller than peak solar radiation energy, such that the photovoltaic material exhibits a multiple exciton effect in response to irradiation by the solar radiation.

30. A method of operating a photovoltaic cell comprising a first electrode, a second electrode, and a photovoltaic material located between and in electrical contact with the first and the second electrodes, the method comprising:
exposing the photovoltaic cell to incident solar radiation propagating in a first direction; and
generating a current from the photovoltaic cell in response to the step of exposing, such that the photovoltaic material exhibits a carrier multiplication effect;
wherein:
a width of the photovoltaic material in a direction substantially perpendicular to an intended direction of incident solar radiation is sufficiently thin to at least one of a) substantially prevent phonon generation during photogenerated charge carrier flight time in the photovoltaic material to at least one of the first and to the second electrodes, or b) substantially prevent charge carrier energy loss due to charge carrier recombination and scattering; and
a height of the photovoltaic material in a direction substantially parallel to the intended direction of incident solar radiation is sufficiently thick to at least one of a) convert at least 90% of incident photons in the incident solar radiation to charge carriers, or b) photovoltaically absorb at least 90% of photons in a 50 to 2000 nm wavelength range.

31. The method of claim 30, wherein the photovoltaic material comprises a first and a second set of semiconductor nanocrystals and the nanocrystals of the first set have a different band gap energy than the nanocrystals of the second set.

32. The method of claim 30, wherein:
the photovoltaic material comprises semiconductor nanocrystals having a band gap that is significantly smaller than peak solar radiation energy, such that the photovoltaic material exhibits the multiple exciton effect in response to the step of exposing;
the width of the photovoltaic material is less than about 200 nm; and
the height of the photovoltaic is at least 1 micron.
